(19) United States
(12) Patent Application Publication
(10) Pub. No.: US 2014/0174713 A1
(43) Pub. Date: Jun. 26, 2014

(54) AIR CONDITIONER CONTROL SYSTEM AND METHOD

(71) Applicant: HON HAI PRECISION INDUSTRY CO., LTD., New Taipei (TW)

(72) Inventor: CHAO-KE WEI, New Taipei (TW)

(73) Assignee: HON HAI PRECISION INDUSTRY CO., LTD., New Taipei (TW)

(21) Appl. No.: 13/859,747

(22) Filed: Apr. 10, 2013

(30) Foreign Application Priority Data
Dec. 25, 2012 (TW) 101149725

(51) Int. Cl. H05K 7/20

(52) U.S. Cl. CPC H05K 7/20836
USPC 165/287

(57) ABSTRACT

An air conditioner control method applied in a container data center includes a container. The container includes a number of server racks and a number of air conditioners. Temperature and humidity values of the container are obtained. The return air temperature value of each air conditioner are obtained when any temperature and humidity of the container is not greater than any value of a preset range. The air conditioner which has the lowest return air temperature is determined when any temperature and humidity of the container is not greater than any value of the preset range. A current mode of the determined air conditioner is then switched to an air supply mode, a rotation speed of the determined air conditioner is increased, and the rotation speed of the remaining air conditioners are decreased. A related air conditioner control system is also provided.

### BACKGROUND

1. Technical Field

The present disclosure relates to containers, and particularly to a system and method capable of controlling air conditioners of a container.

2. Description of Related Art

Air conditioner system are often used to cool a container. However, power consumption of the air conditioner system is high. Therefore, there is a need to provide a system and a method to decrease the power consumption of an air conditioner system while still effectively cooling the container.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a block diagram of a container data center, in accordance with an exemplary embodiment.

FIG. 2 is a schematic view of a container, in accordance with an exemplary embodiment.

FIG. 3 is a block diagram of an air conditioner control system, in accordance with an exemplary embodiment.

FIG. 4 is a flowchart of a method for controlling air conditioners of the container of FIG. 1, in accordance with an exemplary embodiment.

### DETAILED DESCRIPTION

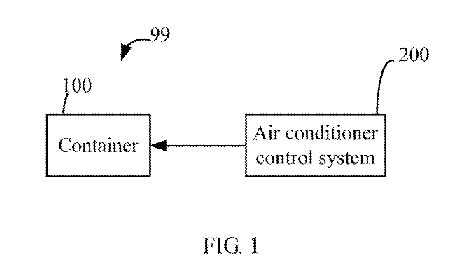

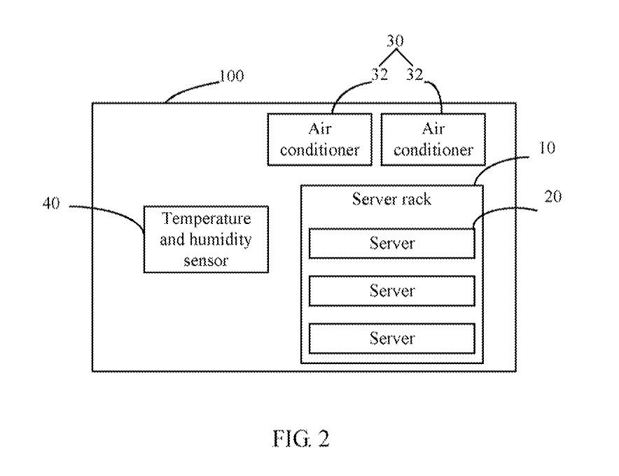

Referring to FIGS. 1-2, a container data center 99 includes a container 100, and an air conditioner control system 200. The container 100 includes a number of server racks 10 (only one server rack 10 is shown in FIG. 2 as an illustration). Each server rack 10 receives a number of servers 20. An air conditioner system 30 is mounted on the server racks 10 to cool the server racks 10. The air conditioner system 30 includes a number of air conditioners 32. The container 100 further includes a temperature and humidity sensor 40 arranged in the container 100 and employed to sense the temperature and humidity of the cooling passage.

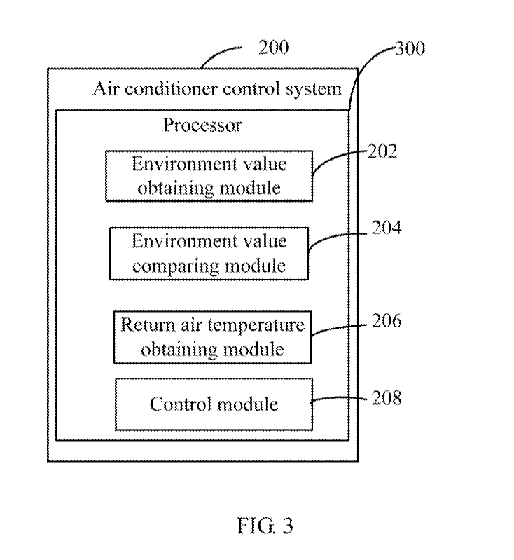

Referring to FIG. 3, the air conditioner control system 200 includes at least one or more processors 300 and a number of modules to be executed by the one or more processors 300. The number of modules include an environment value obtaining module 202, an environment value comparison module 204, a return air temperature obtaining module 206, and a control module 208.

The environment value obtaining module 202 obtains at least one environment value of the container 100 when the container 100 is in a normal state. In this embodiment, the environment value is the temperature value and humidity value of the temperature and humidity sensor 40. In an alternative embodiment, the environment value is or includes a current power consumption value of the container 100.

The environment value comparison module 204 compares the obtained environment value with a preset range. In this embodiment, the preset range includes a preset temperature range and a preset humidity range. In an alternative embodiment, the preset range is or includes a preset power consumption range.

The return air temperature obtaining module 206 obtains the return air temperature value of each air conditioner 32 when each obtained environment value is not greater than any value of the preset range.

When each obtained environment value is less than or equal to any value of the preset value, the control module 208 is operable to determine the air conditioner 32 which has the lowest return air temperature, switch a current mode of the determined air conditioner 32 to an air supply mode, increase the rotation speed of the determined air conditioner 32, and decrease the rotation speed of the remaining air conditioners 32. When the obtained environment value is greater than the maximum value of the preset range, the control module 208 switches the current mode of each air conditioner 32 to a cooling mode, and increases the rotation speed of each air conditioner 32.

In this embodiment, when each obtained environment value is less than or equal to any value of the preset range, it indicates that the heat given off by the container 100 (exhaust heat) is not high. When the exhaust heat of the container 100 is not high, if the return air temperature of one air conditioner 32 is low, it indicates that the exhaust heat of the servers 20 which are cooled by the one air conditioner 32 is also low. Therefore, the current mode of the one air conditioner 32 can be switched to the air supply mode, and the rotation speed of the remaining air conditioners 32 can be decreased, to decrease power consumption of the air conditioner system 30.

When the temperature of the container 100 is too high or the power consumption of the container 100 is too great, the container 100 raises an alarm. In this embodiment, when the container 100 raises an alarm, the control module 208 is further operable to switch the current mode of each air conditioner 32 to the cooling mode, and increase the rotation speed of each air conditioner 32, to avoid any sudden safety cut off in the container 100.

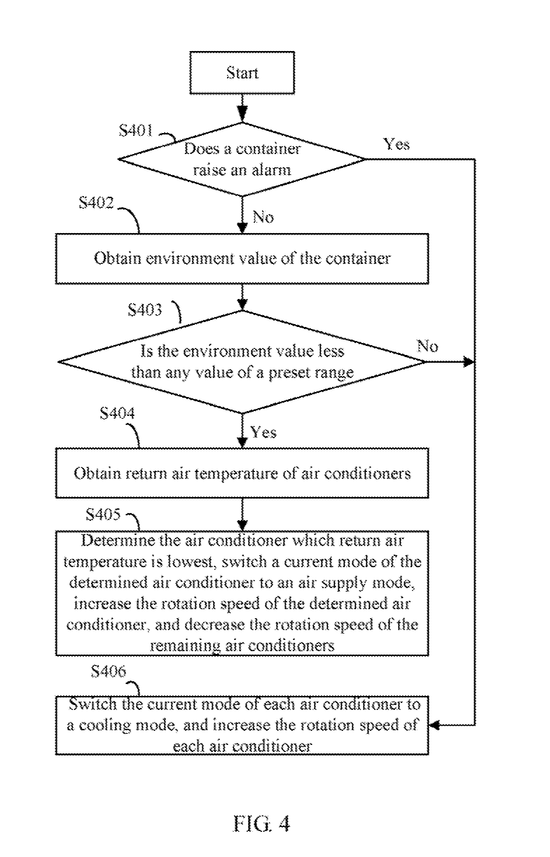

FIG. 4 is a flowchart of an air conditioner control method, in accordance with an exemplary embodiment.

In step S401, the control module 208 determines whether the container 100 raises an alarm. When an alarm is raised, the procedure goes to step S406.

In step S402, the environment value obtaining module 202 obtains at least one environment value of the container 100.

In step S403, the environment value comparison module 204 determines whether each obtained environment value is not greater than any value of the preset range. If yes, the procedure goes to step S404, otherwise, the procedure goes to step S406.

In step S404, the return air temperature obtaining module 206 obtains the return air temperature value of each air conditioner 32.

In step S405, the control module 208 determines the air conditioner 32 which has the lowest return air temperature, switches a current mode of the determined air conditioner to an air supply mode, increases the rotation speed of the determined air conditioner 32, and decreases the rotation speed of the remaining air conditioners 32.

In step S406, the control module 208 switches the current mode of each air conditioner 32 to a cooling mode, and increases the rotation speed of each air conditioner 32.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An air conditioner control system applied in a container data center, the container data center further comprising a container, the container comprising a plurality of server racks and a plurality of air conditioners, the air conditioner control system comprising:
one or more processors; and
a plurality of modules to be executed by the one or more processors, wherein the plurality of modules comprises:
an environment value obtaining module operable to obtain at least one environment value of the container when the container is in a normal state;
an environment value comparison module operable to compare the at least one obtained environment value with at least one preset range;
a return air temperature obtaining module operable to obtain the return air temperature value of each of the plurality of air conditioners when each of the at least one obtained environment value is not greater than any value of the corresponding preset range; and
a control module is operable to determine the air conditioner which has the lowest return air temperature when each of the at least one obtained environment value is not greater than any value of the corresponding preset range, the control module being further operable to switch a current mode of the determined air conditioner to an air supply mode, increase a rotation speed of the determined air conditioner, and decrease the rotation speed of the remaining air conditioners.

2. The air conditioner control system as described in claim 1, wherein when each of the at least one obtained environment value is greater than the maximum value of the corresponding preset range, the control module is further operable to switch the current mode of each of the plurality of air conditioners to a cooling mode, and increase the rotation speed of each of the plurality of air conditioners.

3. The air conditioner control system as described in claim 1, wherein the at least one obtained environment value comprises a temperature value and a humidity value of a cooling passage of the container, and the at least one preset range comprises a preset temperature and a preset humidity range.

4. The air conditioner control system as described in claim 1, wherein the at least one obtained environment value comprises a currently power consumption value of the container, and the preset range comprises a preset power consumption range.

5. The air conditioner control system as described in claim 1, wherein when the container raises an alarm, the control module is further operable to switch the current mode of each of the plurality of air conditioners to a cooling mode, and increase the rotation speed of each of the plurality of air conditioner.

6. An air conditioner control method applied in a container data center, the container data center further comprising a container, the container comprising a plurality of server racks and a plurality of air conditioners, the air conditioner control method to be executed by one or more processors to execute a plurality of steps, the plurality of steps comprising:
obtaining at least one environment value of the container when the container is in a normal state;
comparing the at least one obtained environment value with at least one preset range;
obtaining the return air temperature value of each of the plurality of air conditioners when each of the at least one obtained environment value is not greater than any value of the preset range;
determining the air conditioner which has the lowest return air temperature when each of the at least one obtained environment value is not greater than any value of the preset range; and
switching a current mode of the determined air conditioner to an air supply mode, increasing a rotation speed of the determined air conditioner, and decreasing the rotation speed of the remaining air conditioners.

7. The air conditioner control method as described in claim 6, wherein when each of the at least one obtained environment value is greater than the maximum value of the corresponding preset range, the control module is further operable to switch the current mode of each of the plurality of air conditioners to a cooling mode, and increase the rotation speed of each of the plurality of air conditioners.

8. The air conditioner control method as described in claim 6, wherein the at least one obtained environment value comprises a temperature value and a humidity value of a cooling passage of the container, and the at least one preset range comprises a preset temperature and a preset humidity range.

9. The air conditioner control method as described in claim 6, wherein the at least one obtained environment value comprises a currently power consumption value of the container, and the preset range is a preset power consumption range.

10. The air conditioner control method as described in claim 6, further comprising:
switching the current mode of each of the plurality of air conditioners to a cooling mode and increasing the rotation speed of each of the plurality of air conditioner when the container raises an alarm.
